(19) United States
(12) Patent Application Publication
(10) Pub. No.: US 2009/0061084 A1
(43) Pub. Date: Mar. 5, 2009

(54) VAPOR DEPOSITION SYSTEM AND VAPOR DEPOSITION METHOD

(75) Inventors: Takahide Onuma, Kawasaki-shi (JP); Nobutaka Ukigaya, Yokohama-shi (JP); Takehiko Soda, Yokohama-shi (JP); Kiyoshi Kuramochi, Tokyo (JP); Tomokazu Sushihara, Matsudo-shi (JP); Naohiro Nakane, Tokyo (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/193,612

(22) Filed: Aug. 18, 2008

(30) Foreign Application Priority Data
Sep. 3, 2007 (JP) 2007-227408

(51) Int. Cl. C23C 16/00

(52) U.S. Cl. 427/248.1; 118/715

(57) ABSTRACT

In a vapor deposition method of forming a film of an organic compound on a substrate, a material containing portion filled with a vapor deposition material is heated, to thereby evaporate or sublimate the vapor deposition material and discharge the vapor deposition material to a film formation space of a vacuum chamber through a plurality of pipings connected to the material containing portion, and a piping having a smaller conductance among the pipings having different conductances is provided with a flow rate adjusting mechanism for controlling an amount of the vapor deposition material released into the vacuum chamber, whereby a film formation speed can be adjusted finely.

### BACKGROUND OF THE INVENTION

1. Field of the Invention

The present invention relates to a vapor deposition system and vapor deposition method for manufacturing an organic electroluminescence (EL) device by adhering a vapor deposition material having been evaporated or sublimated to a film formation substrate.

2. Description of the Related Art

Vapor deposition systems used in the manufacture of an organic EL device generally have a vapor deposition source where a vapor deposition material is heated and evaporated and a vacuum chamber where a film formation substrate (substrate) is set. Vapor deposition systems employing a vapor deposition source that is commonly called a point source or a line source can be given as an example of this type of system. Many of vapor deposition sources called point sources or line sources are structured to have an opening in a material containing portion which is filled with a vapor deposition material, and the vapor deposition material is released through the opening. A problem inherent in organic EL device production where a vapor deposition source of this type is employed is that changing materials requires breaking a vacuum in the vacuum chamber.

Another problem is caused by the fact that the flow rate of a vapor deposition material is usually controlled by the heating temperature, which means poor controllability in film formation speed and a difficulty in suppressing or controlling the thermal expansion of the substrate or a mask because heat transferred to the substrate or the mask cannot be made constant.

A solution to those problems can be found in Japanese Patent Application Laid-Open No. 2005-281808 where a vapor deposition source generally called a nozzle source is employed. This method controls the film formation speed by setting the material containing portion in which a material is put outside the vacuum chamber and installing a valve is provided in a piping that connects the material containing portion to the interior of the chamber. With this method, materials can be exchanged without breaking a vacuum and the amount of heat transferred to the substrate or the mask can be kept substantially constant.

In the manufacture of an organic EL device, forming a film at high film formation speed to have an accurate film thickness is necessary in order to improve the productivity and the yield.

However, steady control of the film formation speed is difficult in vapor deposition using a point source or a linear (line) source. Even with a nozzle source, the precision of the film formation speed, which is dependent on the opening/closing precision of the valve, can only be raised to a limited level. When the heating temperature of the material containing portion is high, in particular, the evaporation speed of the vapor deposition material rises exponentially, thereby making steady control more difficult for either method.

### SUMMARY OF THE INVENTION

The present invention has been made in view of the above, and an object of the present invention is therefore to provide a vapor deposition system and a vapor deposition method with which the productivity and the yield in the manufacture of an organic EL device through vapor deposition can be improved by forming a film at high film formation speed to have an accurate film thickness.

According to the present invention, a vapor deposition system for forming a film by adhering a vapor deposition material having been evaporated or sublimated to a film formation substrate, includes: a vacuum chamber with a film formation space in which a film is formed; a material containing portion filled with the vapor deposition material; a unit for evaporating or sublimating the vapor deposition material by heating the material containing portion; a plurality of pipings for supplying the vapor deposition material from the material containing portion to the film formation space of the vacuum chamber; and a unit for controlling a flow rate of the vapor deposition material or releasing/shutting off a flow of the vapor deposition material, in at least one of the plurality of pipings.

According to the present invention, a vapor deposition method of forming a film by adhering a vapor deposition material having been evaporated or sublimated to a film formation substrate, includes: heating a material containing portion filled with the vapor deposition material to evaporate or sublimate the vapor deposition material, and supplying the vapor deposition material into a film formation space of a vacuum chamber through a plurality of pipings connected to the material containing portion; and controlling a flow rate of the vapor deposition material or releasing/shutting off a flow of the vapor deposition material, in at least one of the plurality of pipings to adjust a flow rate of the vapor deposition material supplied to the film formation space of the vacuum chamber.

High film formation speed is achieved by supplying a vapor deposition material to the vacuum chamber through a plurality of pipings. In addition, the film formation speed and the film thickness can be controlled with high precision by providing at least one piping with a unit for controlling the flow rate of a vapor deposition material (flow rate control), or a unit for releasing/shutting off the flow.

An organic EL device can thus be manufactured with high reproducibility in a short period of time, which helps to improve the productivity and the yield.

Further features of the present invention will become apparent from the following description of exemplary embodiment with reference to the attached drawings.

### BRIEF DESCRIPTION OF THE DRAWINGS

FIG. 1 is a schematic sectional view illustrating a vapor deposition system according to Example 1.

FIGS. 2A and 2B are diagrams comparing a vapor deposition source of FIG. 1 against an example of conventional art.

FIGS. 3A and 3B are diagrams illustrating vapor deposition sources according to Examples 2 to 4.

FIG. 4 is a diagram illustrating a modification example of Example 1.

### DESCRIPTION OF THE EMBODIMENTS

An exemplary embodiment of the present invention will be described with reference to the accompanying drawings.

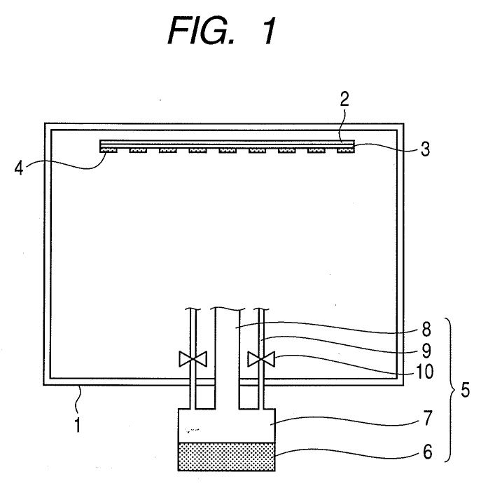

FIG. 1 is a schematic sectional view illustrating a vapor deposition system according to an embodiment of the present invention. This system is used for, for example, the manufacture of an organic EL device (organic light-emitting device). In a film formation space of a vacuum chamber 1, a mask 4 is brought into contact with a device isolation film 3 formed on a substrate 2, which is a film formation substrate. An organic compound as a vapor deposition material is evaporated or sublimated from a vapor deposition source 5 and adhered to the substrate 2 through the mask 4 to form an organic compound film.

The vapor deposition source 5 has a material containing portion 7 filled with a vapor deposition material 6 and a heater (not shown) for heating pipings 8 and 9. The mask 4 is used to deposit an organic compound by evaporation only at given locations on the substrate 2, and is placed on the vapor deposition source side of the substrate 2 in such a manner that the mask 4 is brought into contact with the substrate 2 or is made close to the substrate 2. In FIG. 1, the mask 4 is placed so as to be substantially in contact with a top surface of the device isolation film 3 provided on the substrate 2. A substrate holding mechanism (not shown) is disposed at a back of the substrate 2 to hold the substrate 2 and the mask 4. The interior of the vacuum chamber 1 is exhausted by an exhaust system to a pressure of about 1×10⁻⁴ to 1×10⁻⁵ Pa.

In the vapor deposition source 5, the material containing portion 7 filled with the vapor deposition material 6 is set outside the vacuum chamber 1, and plural pipings 8 and 9 are led from the material containing portion 7 to the interior of the vacuum chamber 1. The vapor deposition material reaches the substrate 2 through the pipings 8 and 9.

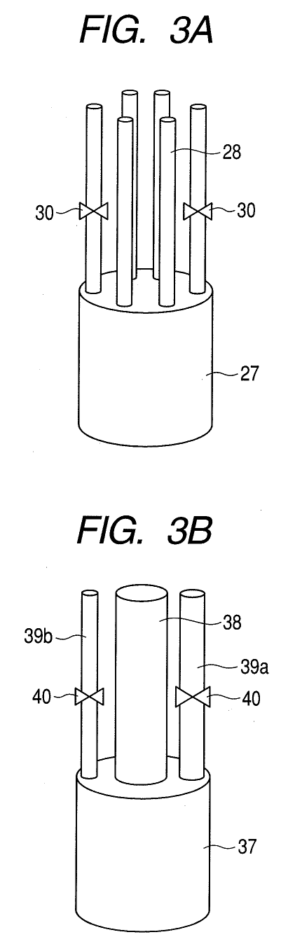

The pipings may all have the same diameter and length. Desirably, the vapor deposition source 5 has the piping 8 with a relatively large conductance and the pipings 9 with a relatively small conductance as illustrated in FIG. 1. The vapor deposition source 5 may also have pipings of three or more different conductances (see FIGS. 3A and 3B).

In whatever combination of different pipings, at least one piping is provided with a flow rate adjusting mechanism 10 which controls the flow rate of the vapor deposition material or which releases/shuts off the flow.

Any number of pipings can be provided for each of different conductances. At least one of the pipings is provided with the flow rate adjusting mechanism 10, which controls the flow rate of the vapor deposition material or which releases/shuts off the flow, such as a valve. The flow rate adjusting mechanism 10 may be installed in a piping that has a relatively large conductance. Desirably, the flow rate adjusting mechanism 10 is installed in every piping or in one or more pipings having relatively small conductance.

According to this embodiment, the piping 8 which has a relatively large conductance enables the vapor deposition system to keep the flow rate of the vapor deposition material high. The flow rate of the vapor deposition material can be controlled by way of the heating temperature or with the use of a valve or other similar unit which controls the flow rate of the vapor deposition material.

The controllability of the flow rate of a vapor deposition material flowing through piping is limited by the controllability of the heating temperature or the controllability of a valve. However, with plural pipings and a valve or the like that controls the flow rate of a material in the pipings or that releases/shuts off the flow, the flow rate of a vapor deposition material can be controlled finely. This effect is particularly prominent when employing the piping 9 of small conductance and installing a flow rate adjusting mechanism 10 such as a valve in the piping 9. Combining the film formation speeds of plural pipings thus enables a vapor deposition system to steadily control the high film formation speed.

Specifically, the piping 8 of large conductance keeps the film formation speed high while the piping 9 of small conductance with the flow rate adjusting mechanism 10, which controls the flow rate of the vapor deposition material or which releases/shuts off the flow, is used for fine control of the film formation speed.

The material containing portion 7 is desirably placed outside the vacuum chamber 1. In this way, when the contained vapor deposition material is used up, the material containing portion 7 can be refilled with a vapor deposition material without breaking the vacuum.

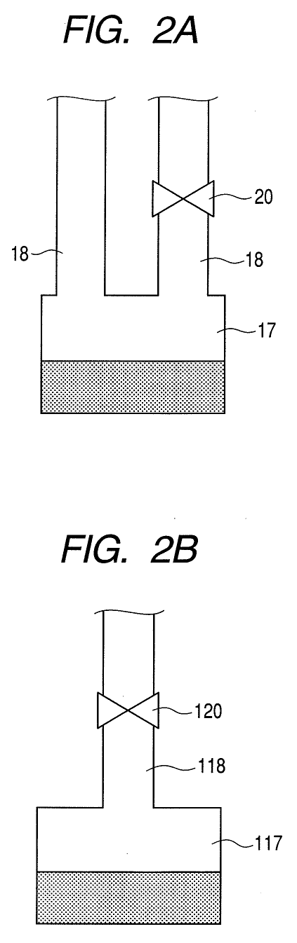

Described next are effects of providing a vapor deposition system with plural pipings and a flow rate adjusting mechanism for controlling the flow rate of a vapor deposition material. FIG. 2A illustrates a material containing portion 17 which has two pipings 18 of the same length and diameter. One of the two pipings 18 is provided with a valve as a flow rate adjusting mechanism 20 which controls the flow rate of a vapor deposition material.

It is assumed that the flow rate control precision of the valve is 3%, the maximum flow rate per piping at a certain temperature is 50 l/s, and the target flow rate of the two pipings 18 combined is 70 l/s.

The piping 18 that does not have the valve lets the material flow at a flow rate of 50 l/s, and the piping 18 that has the valve is controlled by the valve to have a flow rate of 20 l/s. When the material temperature and other system conditions are ideally kept constant, this vapor deposition source can control the flow rate at 70±0.6 l/s.

FIG. 2B illustrates a material containing portion 117 with only one piping 118, which is provided with a valve having a 3% control precision as a flow rate adjusting mechanism 120, and whose maximum flow rate is 100 l/s. When the target flow rate is set to 70 l/s, this vapor deposition source controls the flow rate at 70±2.1 l/s.

It can be seen from the above that plural pipings and a flow rate adjusting mechanism installed in at least one of the pipings enable a vapor deposition system to control the flow rate finely.

When all pipings 28 have the same diameter and length as shown in FIG. 3A where a material containing portion is denoted by 27, a suitable number of pipings 28 are provided with flow rate adjusting mechanisms 30 such as valves which control the flow rate of a vapor deposition material or which release/shut off the flow so that the film formation speed is suitably controlled. Also in this case, the flow rate adjusting mechanisms 30 may be installed in all the pipings.

No particular limitations are put on the structure of the vapor deposition source, the number of the vapor deposition sources, the type of the organic compound employed, and the shape of the opening in the mask. For instance, the opening shape of the vapor deposition source may be dot-like or linear.

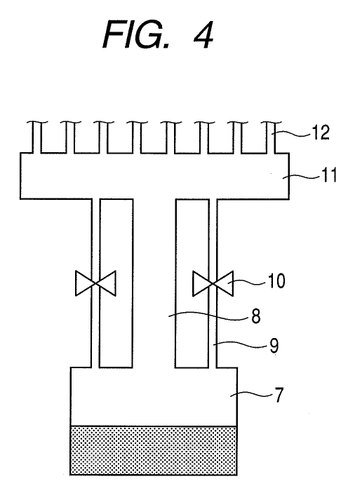

Further, the pipings 8 and 9 in the system of FIG. 1 may be joined by a connection space (connection portion) 11 as illustrated in FIG. 4, where a material containing portion is denoted by 7 and a flow rate adjusting mechanism is denoted by 10. The connection space 11 may be provided with release portions 12 for releasing the vapor deposition material into the film formation space of the vacuum chamber 1.

The vapor deposition source may be a co-deposition source for simultaneously depositing different organic compounds by evaporation.

### EXAMPLE 1

An organic EL device was manufactured on a substrate with the use of the vapor deposition system illustrated in FIG. 1 by the following vapor deposition method. The material containing portion 7 of the vapor deposition source 5 had one piping 8 of large conductance and two pipings 9 of small conductance.

The target film formation speed was set to 2.0 nm/s. The film formation speed immediately above the large conductance piping 8 was kept around 1.9 nm/s. The flow rate of a vapor deposition material in the piping 8 was controlled solely by the heating temperature of the material containing portion 7, but the heating temperature was kept substantially constant. The target film formation speed of the small conductance piping 9 was set such that the film formation speed immediately above the large conductance piping 8 was 0.1 nm/s. The piping 9 was provided with a needle valve as the flow rate adjusting mechanism 10 for controlling the flow rate of the vapor deposition material.

A 400 mm×500 mm non-alkaline glass substrate with a thickness of 0.5 mm was employed as the substrate 2. Thin film transistors (TFTs) and electrode wiring lines were formed into a matrix pattern on the substrate 2 by a usual method. The size of each pixel was set to 30 μm×120 μm, and the pixels were arranged such that a 350 mm×450 mm display area of organic EL devices was formed at the center of the substrate 2. The substrate 2 was placed at a 200 mm distance from the vapor deposition source 5. The substrate 2 was transported at a substantially constant speed during vacuum vapor deposition. The film formation speed was observed with a film thickness rate sensor (not shown), fed back to the needle valve, and utilized for control.

The organic EL device manufacture process employed is described. First, anode electrodes were formed on the glass substrate having TFTs in such a manner that a 25 μm×100 μm light emission area was formed at the center of a pixel. Next, vacuum vapor deposition was conducted using the vapor deposition system of this example, a known vapor deposition mask, and a light emitting material, with the result that the deposition speed of the light emitting material was controlled at 2.0 nm/s±2%. The film thickness of the light emission layer was thus controlled with precision throughout each pixel on the substrate and throughout the substrate, and a high-quality organic EL device was obtained.

### EXAMPLE 2

An organic EL device was manufactured on a substrate with the use of the vapor deposition source illustrated in FIG. 3A. The material containing portion 27 of the vapor deposition source was provided with six pipings 28, which had the same conductance. The pipings 28 were arranged at regular intervals on the top surface of the material containing portion 27, at equidistance from the center of the top surface of the material containing portion 27. Two of the six pipings 28 were provided with needle valves as the flow rate adjusting mechanisms 30 for controlling the flow rate of a vapor deposition material.

The target film formation speed was set to 2.0 nm/s. The target film formation speed of the pipings that do not have the needle valves was set such that film formation speed per piping was 0.45 nm/s immediately above the center of the top surface of the material containing portion 27. The flow rate of a vapor deposition material in those pipings was controlled solely by the heating temperature of the material containing portion 27, but the heating temperature was kept substantially constant.

The target film formation speed of the pipings that have the needle valves was set to 0.1 nm/s per piping immediately above the center of the top surface of the material containing portion 27.

Components used in Example 2 were the same as those of Example 1 except the vapor deposition source.

Vacuum vapor deposition was conducted using the vapor deposition system of this example, a known vapor deposition mask, and a light emitting material, with the result that the film formation speed of the light emitting material was controlled at 2.0 nm/s±2%. The film thickness of the light emission layer was thus controlled with precision throughout each pixel on the substrate and throughout the substrate, and a high-quality organic EL device was obtained.

### EXAMPLE 3

An organic EL device was manufactured on a substrate with the use of the vapor deposition source illustrated in FIG. 3B. The material containing portion 37 of the vapor deposition source was provided with one piping 38 of large conductance, one piping 39a whose conductance was set to an intermediate level, and one piping 39b of small conductance.

The target film formation speed was set to 2.0 nm/s. The film formation speed immediately above the large conductance piping 38 was kept around 1.5 nm/s. The flow rate of a vapor deposition material of the piping 38 was controlled solely by the heating temperature of the material containing portion 37, but the heating temperature was kept substantially constant.

The target film formation speed of the intermediate conductance piping 39a was set such that the film formation speed was 0.45 nm/s immediately above the large conductance piping 38. The piping 39a was provided with a needle valve as a flow rate adjusting mechanism 40 for controlling the flow rate of a vapor deposition material.

The target film formation speed of the small conductance piping 39b was set such that the film formation speed was 0.05 nm/s immediately above the large conductance piping 38. The piping 39b was provided with a needle valve as the flow rate adjusting mechanism 40 for controlling the flow rate of a vapor deposition material.

Components used in Example 3 were the same as those of Example 1 except the vapor deposition source.

Vacuum vapor deposition was conducted using the vapor deposition system of this example, a known vapor deposition mask, and a light emitting material, with the result that the film formation speed of the light emitting material was controlled at 2.0 nm/s±2%. The film thickness of the light emission layer was thus controlled with precision throughout each pixel on the substrate and throughout the substrate, and a high-quality organic EL device was obtained.

### EXAMPLE 4

An organic EL device was manufactured on a substrate with the use of the vapor deposition source illustrated in FIG. 3B. The material containing portion 37 of the vapor deposition source was provided with one piping 38 of large conductance, one piping 39a whose conductance was set to an intermediate level, and one piping 39b of small conductance.

The target film formation speed was set to 2.0 nm/s. The film formation speed immediately above the large conductance piping 38 was kept around 1.5 nm/s. The flow rate of a vapor deposition material of the piping 38 was controlled solely by the heating temperature of the material containing portion 37, but the heating temperature was kept substantially constant.

The target film formation speed of the intermediate conductance piping 39a was set such that the film formation speed was 0.5 nm/s immediately above the large conductance piping 38. The piping 39a was provided with a needle valve as the flow rate adjusting mechanism 40 for releasing/shutting off the flow.

The target film formation speed of the small conductance piping 39b was set such that the film formation speed was 0.02 nm/s immediately above the large conductance piping 38. The piping 39b was provided with a needle valve as the flow rate adjusting mechanism 40 for releasing/shutting off the flow.

Components used in Example 4 were the same as those of Example 1 except the vapor deposition source.

Vacuum vapor deposition was conducted using the vapor deposition system of this example, a known vapor deposition mask, and a light emitting material. During the vacuum vapor deposition, the needle valves were closed when the film formation speed reached 2.03 nm/s and opened when the film formation speed reached 1.97 nm/s. As a result, the film formation speed of the light emitting material was controlled at 2.0 nm/s±2%. The film thickness of the light emission layer was thus controlled with precision throughout each pixel on the substrate and throughout the substrate, and a high-quality organic EL device was obtained.

### COMPARATIVE EXAMPLE 1

An organic EL device was manufactured on a substrate with the use of the vapor deposition source illustrated in FIG. 2B. The material containing portion 117 of the vapor deposition source was provided with only one piping 118. The piping 118 was provided with a needle valve as the flow rate adjusting mechanism 120 for controlling the flow rate of a vapor deposition material. The target film formation speed was set to 2.0 nm/s. Components used in Comparative Example 1 were the same as those of Example 1 except the vapor deposition source.

Vacuum vapor deposition was conducted using the vapor deposition system of this comparative example, a known vapor deposition mask, and a light emitting material, with the result that the film formation speed of the light emitting material fluctuated around 2.0 nm/s±5%. A measurement made after the vapor deposition revealed that the film thickness of the light emission layer formed by the vapor deposition was not uniform throughout the glass substrate. Accordingly, there was unevenness to an image displayed by the obtained organic EL device.

While the present invention has been described with reference to exemplary embodiment, it is to be understood that the invention is not limited to the disclosed exemplary embodiment. The scope of the following claims is to be accorded the broadest interpretation so as to encompass all such modifications and equivalent structures and functions. This application claims the benefit of Japanese Patent Application No. 2007-227408, filed Sep. 3, 2007, which is hereby incorporated by reference herein in its entirety.

What is claimed is:

1. A vapor deposition system for forming a film by adhering a vapor deposition material having been evaporated or sublimated to a substrate, comprising:
a vacuum chamber with a film formation space in which a film is formed;
a material containing portion filled with the vapor deposition material;
a unit for evaporating or sublimating the vapor deposition material by heating the material containing portion;
a plurality of pipings for supplying the vapor deposition material from the material containing portion to the film formation space of the vacuum chamber; and
a unit for controlling a flow rate of the vapor deposition material or releasing/shutting off a flow of the vapor deposition material, in at least one of the plurality of pipings.

2. The vapor deposition system according to claim 1, further comprising:
a connection portion which connects the plurality of pipings; and
release portions through which the vapor deposition material is released from the connection portion into the film formation space of the vacuum chamber.

3. The vapor deposition system according to claim 1, further comprising a unit for heating each of the plurality of pipings.

4. The vapor deposition system according to claim 1, wherein the plurality of pipings include pipings having different conductances.

5. The vapor deposition system according to claim 4, wherein at least one of the plurality of pipings that has a small conductance is provided with the unit for controlling the flow rate of the vapor deposition material or releasing/shutting off the flow of the vapor deposition material.

6. The vapor deposition system according to claim 1, wherein the material containing portion is provided outside the vacuum chamber.

7. A vapor deposition method of forming a film by adhering a vapor deposition material having been evaporated or sublimated to a substrate, comprising:
heating a material containing portion filled with the vapor deposition material to evaporate or sublimate the vapor deposition material, and supplying the vapor deposition material into a film formation space of a vacuum chamber through a plurality of pipings connected to the material containing portion; and
controlling a flow rate of the vapor deposition material or releasing/shutting off a flow of the vapor deposition material, in at least one of the plurality of pipings to adjust a flow rate of the vapor deposition material supplied to the film formation space of the vacuum chamber.
